(19) United States
(12) Patent Application Publication
(10) Pub. No.: US 2012/0048598 A1
(43) Pub. Date: Mar. 1, 2012

(54) ADHESIVE RESIN COMPOSITION, AND LAMINATE AND FLEXIBLE PRINTED WIRING BOARD USING THE SAME

(76) Inventors: Shingo Kaimori, Osaka (JP); Jun Sugawara, Osaka (JP); Akira Mizoguchi, Osaka (JP); Syougo Asai, Shiga (JP); Takuma Yoshisaka, Shiga (JP); Naota Uenishi, Osaka (JP)

(21) Appl. No.: 13/318,304

(22) PCT Filed: Mar. 26, 2010
(86) PCT No.: PCT/JP2010/055317

§ 371 Date: Oct. 31, 2011

(30) Foreign Application Priority Data
Apr. 30, 2009 (JP) 2009-111508

(51) Int. Cl. H05K 1/00; C09J 133/14; C09J 171/10; C09J 11/02; B32B 27/38; C09J 163/00

(52) U.S. Cl. 174/254; 428/355 EP; 525/113; 525/132; 525/150; 524/80

(57) ABSTRACT

Provided is an adhesive resin composition containing an epoxy resin and/or a phenoxy resin; an epoxy-containing copolymer obtained by copolymerizing a monomer having an epoxy group and an ethylenically unsaturated monomer that is copolymerizable with the monomer having an epoxy group; a thermoplastic resin; and a curing agent, wherein a copolymer having a weight-average molecular weight of 5,000 to less than 100,000 and a weight per epoxy equivalent of 3,500 g/eq or less is used as the epoxy-containing copolymer. The adhesive resin composition is capable of providing a one-part type adhesive solution that has a good compatibility of the polymer components, that has good flame retardancy and is halogen-free, and that has good storage stability. Also provided are a laminate and a flexible printed wiring board that use the adhesive resin composition.

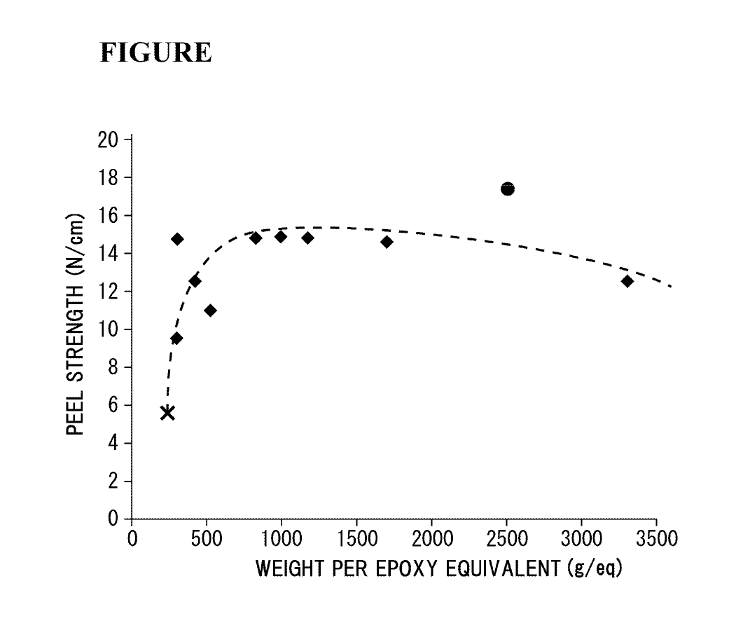

### TECHNICAL FIELD

The present invention relates to an adhesive resin composition suitable for use in a flexible printed wiring board such as a flexible copper-clad laminated board, in particular, to an adhesive resin composition that can be used as a one-part type resin composition, and a flexible printed wiring board and laminates such as an adhesive sheet and a coverlay film using the adhesive resin composition.

### BACKGROUND ART

In general, flexible printed wiring boards have a basic structure in which a copper foil or the like is bonded with an adhesive to one surface or both surfaces of an insulating film used as a base material, the insulating film being composed of a heat-resistant film such as a polyimide film.

As such an adhesive used in a flexible printed wiring board, hitherto, adhesive compositions containing, as main components, a thermosetting resin such as an epoxy resin which contributes to chemical resistance, heat resistance, and mechanical strength, and a reactive rubber such as acrylonitrile-butadiene rubber which has a function of imparting a high adhesion property and flexibility have been mainly used.

From the standpoint of the ease of the production process control, film-type adhesives have been proposed. Such film-type adhesives are obtained by applying an adhesive composition onto a film that has been subjected to a parting treatment, and drying the adhesive composition, and are stored in a semi-hardened state (B-stage state). Therefore, hardening may gradually proceed during storage, and a desired adhesive strength may not be obtained.

As a film-type adhesive for a flexible substrate, the film-type adhesive having a high storage stability and a good peel strength, for example, PTL 1 (Japanese Unexamined Patent Application Publication No. 2002-275444) has proposed an adhesive resin composition containing an epoxy resin, an epoxy resin curing agent, and an epoxy-group-containing (meth)acrylic copolymer containing 0.5% to 2.7% by weight of an epoxy-group-containing repeating unit and having a weight-average molecular weight of 100,000 or more. Here, a ratio A/B of the total weight A of the epoxy resin and the epoxy resin curing agent to the weight B of the epoxy group-containing (meth)acrylic copolymer is 0.25 to 3.

Meanwhile, as an adhesive composition for a flexible substrate, the adhesive composition being capable of dissolving in an organic solvent and being used as an adhesive varnish, for example, PTL 2 (Japanese Unexamined Patent Application Publication No. 2008-81678) has proposed an adhesive resin composition containing a thermosetting resin such as an epoxy resin, a monomer having at least two ethylenically polymerizable unsaturated groups, e.g. isoprene, a monomer having an alcoholic hydroxyl group, and a copolymer containing a styrene derivative or a (meth)acrylic acid derivative. It is disclosed that such a copolymer has a satisfactory compatibility with epoxy resins, and can impart a sufficient adhesive strength and toughness to resins that are generally believed to be hard and brittle.

As an epoxy adhesive that is used in a flexible printed wiring board or the like and that is intended for being used as a liquid adhesive, PTL 3 (Japanese Unexamined Patent Application Publication No. 2008-308686) has proposed an adhesive in which 10 to 100 parts by weight of an epoxidized styrene thermoplastic elastomer is incorporated to 100 parts by weight of a base resin containing an epoxy resin and a curing agent.

Furthermore, hitherto, halogen flame retardants have been used in order to impart flame retardancy. However, in view of the requirements of recent non-halogen flame retardants, the use of phosphorus flame retardants, and furthermore, the use of phosphorus-containing resins as resins have been proposed. For example, a phosphorus-containing epoxy resin has been used as an epoxy resin. For example, as an adhesive resin composition for a flexible printed wiring board, the adhesive resin composition being intended to be used as a film-type adhesive, PTL 4 (Japanese Unexamined Patent Application Publication No. 2004-307627) has proposed a flame retardant adhesive containing 0% to 15% by weight of an epoxy resin, 10% to 30% by weight of a phosphorus-containing epoxy resin, and an acrylic resin obtained by polymerizing an epoxy-group containing (meth)acrylate monomer, acrylonitrile, and another copolymerizable monomer, the acrylic resin having a weight-average molecular weight of 500,000 to 1,000,000.

### SUMMARY OF INVENTION

### Technical Problem

As described above, various adhesive compositions for a flexible printed wiring board, in particular, components which impart a high adhesion property and flexibility and which are used in the resin compositions have been proposed. However, recent demands for further improving flame retardancy, heat resistance, chemical resistance, and mechanical strength have been further increasing. In order to meet these demands, for example, an increase in the content percentage of a thermosetting resin such as an epoxy resin, and incorporation of a phosphorus-containing epoxy resin or the like are conceivable. In these cases, however, the compatibility among components in the composition tends to decrease, and it is difficult to obtain a uniform liquid adhesive. Even if the components are dispersed by forced mixing, the mixing components are separated during coating, or aggregation and gelation occur, resulting in an uneven coating. As a result, new problems in that desired characteristics such as adhesive strength are not obtained and the characteristics significantly vary between products occur.

The present invention has been made in view of the above circumstance. An object of the present invention is to provide an adhesive resin composition capable of providing a one-part type adhesive solution which is a halogen-free adhesive solution having good flame retardancy, and which also has good storage stability, and a laminate and a flexible printed wiring board using the same.

### Solution to Problem

An adhesive resin composition of the present invention contains (A) an epoxy resin and/or a phenoxy resin; (B) an epoxy-containing copolymer obtained by copolymerizing a monomer having an epoxy group and an ethylenically unsaturated monomer that is copolymerizable with the monomer having an epoxy group; (C) a thermoplastic resin; and (D) a curing agent, wherein the epoxy-containing copolymer (B) has a weight-average molecular weight of 5,000 to less than 100,000 and a weight per epoxy equivalent of 3,500 g/eq or less.

An ethylenically unsaturated monomer unit in the epoxy-containing copolymer (B) is preferably at least one selected from the group consisting of styrenes, acrylonitrile, and (meth)acrylate esters.

The content percentage of the component (A) in the resin components contained in the adhesive resin composition is preferably 40% to 70% by mass, and the content percentage of the component (B) is preferably 3% to 25% by mass.

The monomer having an epoxy group in the epoxy-containing copolymer (B) is preferably glycidyl(meth)acrylate. The epoxy resin and/or phenoxy resin (A) preferably contains a phosphorus-containing epoxy resin and/or a phosphorus-containing phenoxy resin.

Preferably, the adhesive resin composition of the present invention further contains a phosphorus flame retardant, wherein the phosphorus content percentage in the resin composition is 3.1% to 4.5% by mass.

The adhesive resin composition of the present invention is suitably used as a one-part type adhesive solution containing the adhesive resin composition, wherein the content percentage of the adhesive resin composition is 5% to 60% by mass. Furthermore, the present invention includes a laminate including a base material film and an adhesive layer disposed on the base material film, the adhesive layer being composed of the adhesive resin composition of the present invention, and a flexible printed wiring board including the laminate.

### ADVANTAGEOUS EFFECT OF INVENTION

The adhesive resin composition of the present invention is good in terms of compatibility among polymer components incorporated therein, and thus it is possible to provide a one-part type adhesive solution having good storage stability, and also to satisfy flame retardancy even though this adhesive solution is halogen-free.

### BRIEF DESCRIPTION OF DRAWING

FIGURE is a graph showing a relationship between the weight per epoxy equivalent (horizontal axis) and the peel strength (vertical axis) of adhesive solutions used in Examples.

### DESCRIPTION OF EMBODIMENTS

Embodiments of the present invention will now be described. However, it is to be understood that the embodiments disclosed herein are illustrative in all respects and are not restrictive. It is intended that the scope of the present invention is defined by Claims and includes equivalents of Claims and all modifications within the scope of Claims.

### [Adhesive Resin Composition]

An adhesive resin composition of the present invention contains (A) an epoxy resin and/or a phenoxy resin; (B) an epoxy-containing copolymer obtained by copolymerizing a monomer having an epoxy group and an ethylenically unsaturated monomer that is copolymerizable with the monomer having an epoxy group, and having a specific weight-average molecular weight and a specific weight per epoxy equivalent; (C) a thermoplastic resin, and (D) a curing agent.

The components will be described in order.
(A) Epoxy Resin and/or Phenoxy Resin

An adhesive resin composition of the present invention contains an epoxy resin and/or a phenoxy resin.

The epoxy resin used in the present invention may be any resin as long as the resin has at least two epoxy groups in one molecule. Examples thereof include bisphenol A epoxy resins, bisphenol F epoxy resins, glycidyl ether epoxy resins, glycidyl ester epoxy resins, glycidylamine epoxy resins, novolac epoxy resins, and cresol novolak epoxy resins.

The same as the above applies to epoxy resins having high molecular weights and classified as phenoxy resins. Adhesives containing a phenoxy resin or an epoxy resin having a high molecular weight are preferable. The reasons for this are as follows. Such adhesives are advantageous, for example, in that it is easy to control the cure extent in a coverlay or an adhesive sheet in a semi-hardened state, and that the lifetime is long. Also, such adhesives are advantageous, for example, in that a desired adhesion property and desired mechanical properties can be obtained by heating for a short time, and thus high productivity can be achieved in the production of a copper clad laminate (CCL) and the production of a flexible printed circuit (FPC), and that such adhesives have good flow characteristics.

From the standpoint of flame retardancy, it is preferable to use phosphorus-containing epoxy resins and phosphorus-containing phenoxy resins in which phosphorus atoms are bonded to any of the above epoxy resins and phenoxy resins, respectively, using a reactive phosphorus compound. These phosphorus-containing epoxy resins and phosphorus-containing phenoxy resins exhibit a flame retardant effect due to phosphorus, and thus the content of a non-halogen flame retardant can be reduced, and consequently, it is possible to prevent a decrease in the adhesive strength and the mechanical strength due to the incorporation of the flame retardant. However, with an increase in the phosphorus content, the solubility in solvents and the compatibility with other resins tend to decrease. Therefore, the phosphorus content in the epoxy resin or the phenoxy resin is preferably 2% to 6% by mass relative to the mass of epoxy and phenoxy molecules to which phosphorus is incorporated.

Commercially available phosphorus-containing epoxy resins and phosphorus-containing phenoxy resins may be used. Examples thereof include FX289, FX305, and ERF001 manufactured by Tohto Kasei CO., LTD., and EPICLON EXA-9710 manufactured by DIC Corporation.

The weight-average molecular weights of the epoxy resin and the phenoxy resin are not particularly limited. However, with an increase in the molecular weight, the solubility in solvents and the compatibility of the epoxy resin with other resins tend to decrease. Regarding the phenoxy resin, this tendency is stronger. Therefore, it is preferable to appropriately determine the weight-average molecular weights of these resins in consideration of the relationship with the compatibility in accordance with the types of resins used.

The epoxy resins and the phenoxy resins described above may be used alone or as a mixture of two or more resins. An epoxy resin and a phenoxy resin may be mixed and used. Furthermore, a phosphorus-containing epoxy resin and/or a phosphorus-containing phenoxy resin may be mixed with an epoxy resin that does not contain phosphorus and/or a phenoxy resin that does not contain phosphorus, and the mixture may be used.

Furthermore, thermosetting resins other than epoxy resins, for example, phenol resins, melamine resins, and oxazine resins may also be added.

The content percentage of the epoxy resin and/or phenoxy resin (A) in the adhesive resin composition is not particularly limited. However, the epoxy resin and/or phenoxy resin (A) is preferably incorporated in an amount of 40% to 70% by mass relative to the amount of resin components contained in the adhesive resin composition of the present invention (i.e., the total amount of the component (A), the component (B), and the component (C), and, if another thermosetting resin is further contained, the amount determined by adding the amount of the other thermosetting resin to the total amount of the components (A), (B), and (C)).

### (B) Epoxy-Containing Copolymer

An epoxy-containing copolymer used in the present invention is a copolymer obtained by copolymerizing a monomer having an epoxy group and an ethylenically unsaturated monomer that is copolymerizable with the monomer having an epoxy group. The epoxy-containing copolymer has a weight-average molecular weight of 5,000 to less than 100,000, and a weight per epoxy equivalent of 3,500 g/eq or less.

The weight-average molecular weight of the epoxy-containing copolymer (B) used in the present invention is 5,000 to less than 100,000, preferably 6,000 to 80,000, and more preferably, 8,000 to 28,000.

If the weight-average molecular weight is less than 5,000, the mechanical strength of the resulting adhesive layer tends to be insufficient. On the other hand, if the weight-average molecular weight is 100,000 or more, the compatibility is poor, and thus a transparent adhesive solution is not easily obtained, and the storage stability is poor.

Instead of using the epoxy-containing copolymer (B), in general, the above components are mixed in the form of monomers, which have a good compatibility, and a polymerization reaction is then conducted by heating. However, it takes a long time for the reaction to proceed, and monomers that are not sufficiently subjected to a reaction, a remaining initiating reagent, and a remaining reaction accelerator affect the properties of the resulting hardened material. Furthermore, the reaction gradually proceeds during storage and gelation occurs, resulting in a problem in terms of storage stability. Therefore, this method is not preferable. Accordingly, it is preferable to use the epoxy-containing copolymer (B) having a weight-average molecular weight of 5,000 or more, in which the polymerization reaction has proceeded to a certain degree.

The weight per epoxy equivalent of the epoxy-containing copolymer (B) is 3,500 g/eq or less, preferably 3,000 g/eq or less, and more preferably 2,000 g/eq or less. If the weight per epoxy equivalent exceeds 3,500 g/eq, the compatibility with the component (A) and the component (C) decreases, though it depends on the molecular weight. As a result, for example, when the composition is dissolved in an organic solvent, the solution may be separated into two layers or an emulsion may be obtained. Thus, an adhesive solution having low storage stability is obtained. Even when such an adhesive solution that is separated into two layers is forcibly dispersed and applied, the adhesive strength is insufficient, and variations among products become significant.

On the other hand, the lower limit of the weight per epoxy equivalent of the epoxy-containing copolymer (B) is not particularly limited. However, the weight per epoxy equivalent of a homopolymer obtained by polymerizing only a monomer having an epoxy group is usually about 200 to 500 g/eq. In such a homopolymer obtained by polymerizing only a monomer having an epoxy group, even when the weight-average molecular weight is 5,000 to 100,000, the effect of improving the adhesive strength due to the addition of the component (B) is insufficient. Therefore, preferably, the weight per epoxy equivalent of the epoxy-containing copolymer (B) is substantially 200 g/eq or more.

The monomer having an epoxy group may be any compound as long as the compound has a copolymerizable unsaturated bond and an epoxy group in a side chain thereof. Glycidyl group-containing unsaturated monomers are preferably used. Specific examples thereof include glycidyl esters of unsaturated carboxylic acids, such as glycidyl acrylate, glycidyl methacrylate, itaconic acid monoglycidyl ester, and butene tricarboxylic acid monoglycidyl ester; and glycidyl ethers such as vinyl glycidyl ether, allyl glycidyl ether, and glycidyloxyethyl vinyl ether. Among these, glycidyl acrylate and glycidyl methacrylate are preferably used.

Examples of the ethylenically unsaturated monomer copolymerized with the monomer having an epoxy group include styrene monomers such as styrene, nucleus-substituted styrenes, e.g., o-, m-, and p-methylstyrenes, dimethylstyrene, ethylstyrene, and chlorostyrene, and styrene derivatives, e.g., as α-methylstyrene, α-chlorostyrene, and β-chlorostyrene; olefins such as ethylene and propene; vinyl esters such as vinyl acetate, vinyl propionate, and vinyl benzoate; α,β-unsaturated carboxylic acids such as acrylic acid, methacrylic acid, itaconic acid, and maleic acid; salts of these α,β-unsaturated carboxylic acids; alkyl esters of (meth)acrylic acids such as methyl(meth)acrylate, ethyl (meth)acrylate, and propyl(meth)acrylate; amides such as acrylamide and methacrylamide; and nitriles such as acrylonitrile. These monomers may be used alone or in combination of two or more monomers.

Among these, monomers selected from the group consisting of styrene monomers, alkyl esters of (meth)acrylic acids, and nitriles are preferably used.

In particular, epoxy-containing copolymers copolymerized with an acrylonitrile monomer are preferable because the adhesive strength is improved as compared with epoxy-containing copolymers in which other ethylenically unsaturated monomers are incorporated. However, when the amount of acrylonitrile monomer is increased in the copolymerization system, an unreacted acrylonitrile monomer tends to remain and is incorporated in the epoxy-containing copolymer, thereby causing adverse effects in some cases. Therefore, the content percentage of the acrylonitrile monomer unit in the epoxy-containing copolymer is preferably 1% to 20% by mass, and more preferably 1% to 15% by mass.

The use of a styrene monomer unit also easily achieves a high peel strength. With an increase in the content percentage of the styrene monomer unit, the adhesion property tends to improve. Therefore, the content percentage of the styrene monomer unit in the epoxy-containing copolymer (B) may be determined so that the remaining portion is composed of the styrene monomer unit from the standpoint of a requirement that the weight per epoxy equivalent satisfies the above range.

On the other hand, in the case where a monomer having a reactive functional group, such as a carboxyl group-containing monomer, a hydroxy group-containing monomer, or an amino-group containing monomer is used as a copolymerizable monomer having a polar group, a hardening reaction with other resins (in particular, an epoxy resin and a phenoxy resin) gradually occurs during storage, and the pot life of an adhesive solution and the homogeneity of the adhesive solution may be impaired. Accordingly, the content of such an ethylenically unsaturated monomer having any of these polar groups is preferably small.

In addition, it is not preferable to incorporate a diene monomer such as butadiene, which is a so-called rubber component, because such a diene monomer may decrease weather resistance and heat resistance.

The epoxy-containing copolymer used in the present invention is obtained by copolymerizing the monomers described above. The epoxy-containing copolymer may be a random copolymer of the monomer having an epoxy group and the ethylenically unsaturated monomer, or a block copolymer or graft copolymer in which polymerized segments of the monomer having an epoxy group and polymerized segments of the ethylenically unsaturated monomer are bonded to each other.

In the case where two or more types of ethylenically unsaturated monomers are copolymerized, each type of the monomer may be randomly polymerized with the monomer having an epoxy group, or the resulting copolymer may be a tri-block copolymer or a tetra-block copolymer in which blocks of each type of the monomer are properly combined with blocks of the monomer having an epoxy group, or a copolymer in which a plurality of monomers are randomly copolymerized with respective blocks.

An epoxy-group containing polymer may be similarly obtained by copolymerizing a monomer having a functional group other than an epoxy group, and then substituting the functional group with an epoxy group. However, in synthesizing a polymer in which an epoxy group is incorporated in a high concentration, the polymer having a weight per epoxy equivalent of 3,500 g/eq or less, preferably 3,000 g/eq or less, and more preferably 2,000 g/eq or less, such a polymer can be easily obtained by polymerizing a monomer having an epoxy group, and thus this method is preferable.

Commercially available epoxy-containing copolymer having the above configuration may be used. Examples thereof include Marproof G series manufactured by NOF CORPORATION.

The epoxy-containing copolymer (B) having the above configuration has a function of imparting adhesive strength and flexibility. In addition, since the epoxy-containing copolymer (B) has a good compatibility with the epoxy resin and/or the phenoxy resin which is the component (A) and the thermoplastic resin which is the component (C), a uniform liquid adhesive can be provided. Furthermore, since a hydroxy group or the like that is produced by a reaction of an epoxy group in the epoxy-containing copolymer (B) can form a cross-linked structure with the component (A), good mechanical properties can be imparted.

The content percentage of the epoxy-containing copolymer (B) in the adhesive resin composition of the present invention is not particularly limited. However, the epoxy-containing copolymer (B) is preferably incorporated in an amount of 3% to 25% by mass and more preferably 3% to 20% by mass relative to the amount of resin components contained in the adhesive resin composition of the present invention (i.e., the total amount of the component (A), the component (B), component (C), and, if another thermosetting resin is further contained, the amount determined by adding the amount of the other thermosetting resin to the total amount of the components (A), (B), and (C)). If the content percentage of the epoxy-containing copolymer (B) is less than 3% by mass, the effect of improving the adhesion property due to the incorporation of the epoxy-containing copolymer is not obtained. On the other hand, if the content percentage exceeds 25% by mass, the compatibility with the component (A) and the component (C) decreases, resulting in a decrease in the storage stability of the adhesive and the adhesive strength.

### (C) Thermoplastic Resin

Examples of the thermoplastic resin (C) include, but are not particularly limited to, acrylic resins, polystyrene resins, polyamide resins, polyamideimide resins, polyester resins, polycarbonate resins, polyphenylene oxide resins, polyphenylene sulfide resins (such as polyphenylene sulfide, polyphenylene sulfide ketone, and polyphenylene sulfide sulfone), polysulfone resins (such as polysulfone and polyethersulfone), polyetherimide resins (such as a poly(N-formylethyleneimine) resin), polyether ether ketone resins, polyacetal resins (such as a polyoxymethylene resin), and ketone resins (such as aliphatic polyketone resins, an acetone-formaldehyde resin, an acetone-furfural resin, and cyclic ketone resins). These thermoplastic resins may be used alone or in combination of two or more resins.

Among these thermoplastic resins, in consideration of the compatibility with the epoxy resin and/or the phenoxy resin (A) and the epoxy-containing copolymer (B) and the adhesion property, polyamide resins are preferably used.

Thermoplastic resins in which phosphorus is incorporated in their molecules are preferable because such thermoplastic resins have good flame retardancy and thus the amount of flame retardant can be reduced, and it is possible to prevent a decrease in the adhesive strength, the decrease being caused by the incorporation of the flame retardant. Examples of commercially available phosphorus-containing thermoplastic resins include VYLON 237, 337, 537, and 637, and UR3570, all of which are manufactured by TOYOBO CO., LTD.

The polyamide resins can be synthesized by a reaction of a dicarboxylic acid, a diamine, an aminocarboxylic acid, a lactam, and the like. The reaction is not limited to a reaction between one dicarboxylic acid and one diamine. Alternatively, the polyamide resin may be synthesized by using a plurality of dicarboxylic acids and a plurality of diamines.

Examples of the dicarboxylic acid include terephthalic acid, isophthalic acid, orthophthalic acid, naphthalenedicarboxylic acids (1,5-, 2,5-, 2,6-, and 2,7-isomers) acids, biphenyldicarboxylic acids (2,2′-, 3,3′-, and 4,4′-isomers), 4,4′-diphenyl ether dicarboxylic acid, 4,4′-diphenylmethane dicarboxylic acid, 4,4′-diphenyl sulfone dicarboxylic acid, 1,2-bis(phenoxy)ethane-4,4′-dicarboxylic acid, anthracene-2,5-dicarboxylic acid (2,5- and 2,6-isomers), phenylene diacetic acids (o-, m-, and p-isomers), phenylene dipropionic acids (o-, m-, and p-isomers), phenylmalonic acid, phenylglutaric acid, diphenylsuccinic acid, oxalic acid, malonic acid, succinic acid, glutaric acid, hexanedioic acid, sebacic acid, decanedicarboxylic acid, maleic acid, fumaric acid, itaconic acid, 1,3-cyclobutanedicarboxylic acid, 1,3-cyclopentanedicarboxylic acid, 1,4-cyclohexanedicarboxylic acid, 1,2-cyclohexanedicarboxylic acid, 1,3-dicarboxymethyl cyclohexane, 1,4-dicarboxymethyl cyclohexane, dicyclohexyl-4,4′-dicarboxylic acid, and dimer acids.

Examples of the diamine include hexamethylenediamine, heptamethylenediamine, p-di-aminomethyl cyclohexane, bis(p-aminecyclohexyl)methane, m-xylene diamine, 1,4-bis(3-aminopropoxy)cyclohexane, piperazine, and isophorone diamine.

Examples of the aminocarboxylic acid include 11-aminoundecanoic acid, 12-aminododecanoic acid, 4-aminomethylbenzoic acid, 4-aminomethylcyclohexane carboxylic acid, 7-aminoenanthic acid, and 9-aminononanoic acid.

Examples of the lactam include ε-caprolactam, ω-laurolactam, α-pyrrolidone, and α-piperidone.

Among these, in particular, polyamides containing a dimer acid as a component are obtained by a common polycondensation of a dimer acid and a diamine. In this case, a dicarboxylic acid other than the dimer acid, such as hexanedioic acid, azelaic acid, or sebacic acid, may be contained as a copolymer.

As the above-described thermoplastic resins, thermoplastic resins having a glass transition temperature of 70° C. or lower are preferably used. This is because if the glass transition temperature is excessively high, the handleability decreases. In addition, if the glass transition temperature is excessively high, the adhesion property tends to decrease.

### (D) Curing Agent

Any compound used as a curing agent of epoxy resins and phenoxy resins can be used as the curing agent. For example, polyamine curing agents, acid anhydride curing agents, boron trifluoride-amine complexes, imidazole curing agents, aromatic diamine curing agents, carboxylic acid curing agents, and phenol resins are used.

Examples of the polyamine curing agents include aliphatic amine curing agents such as diethylenetriamine and tetraethylenetetramine; alicyclic amine curing agents such as isophorone diamine; aromatic amine curing agents such as diaminodiphenyl methane and phenylenediamine; and dicyandiamide. Examples of the acid anhydride curing agents include acid phthalic anhydride, pyromellitic dianhydride, trimellitic anhydride, and hexahydrophthalic anhydride.

The amount of curing agent mixed is appropriately determined in accordance with the weight per epoxy equivalent of the epoxy resin which is the component A.

### (E) Others

The resin composition of the present invention may further contain non-halogen flame retardants, preferably, phosphorus flame retardants, besides the thermosetting resin, the thermoplastic resin, and the curing agent described above.

Examples of the non-halogen flame retardants that can be used in the present invention include phosphorus compounds such as phosphoric esters, phosphate amides, phosphazenes, and 9,10-dihydro-9-oxa-10-phosphaphenanthrene-10-oxide. Among these, phosphazenes are preferably used from the standpoint of the phosphorus concentration and the solubility in a solvent. The term “phosphazene” is a common name of a group of compounds having a double bond and containing phosphorus and nitrogen as constituent elements. The phosphazene is not particularly limited as long as the compound has a phosphazene structure in its molecule. The phosphazene may be a cyclophosphazene having a cyclic structure, or a linear polymer or oligomer obtained by conducting ring-opening polymerization of the cyclophosphazene.

In the case where a non-halogen flame retardant is incorporated, the adhesion property decreases with an increase in the content percentage of the flame retardant. Thus, the content percentage of the non-halogen flame retardant is preferably, at a maximum, 30 parts by mass or less per 100 parts by mass of the resins.

It should be noted that, preferably, a metalhydroxide (inorganic filler) such as magnesium hydroxide or aluminum hydroxide is not incorporated as the non-halogen flame retardant because such a metalhydroxide causes a decrease in the adhesion property.

### [Preparation of Adhesive Resin Composition and Adhesive Solution]

The adhesive resin composition of the present invention is prepared by mixing the components (A) to (D) described above, and as required, a non-halogen flame retardant, and other additives.

The adhesive resin composition is preferably prepared so that the phosphorus content percentage in the resin composition is 3.1% to 4.5% by mass.

In addition, a hardening accelerator, a silane coupling agent, a leveling agent, an antifoaming agent, and other additives may be mixed as required. However, in the case where a phosphorus-containing epoxy resin is used and a benzoxazine compound is incorporated, addition of a hardening accelerator tends to shorten the pot life of the adhesive and degrade the adhesion property. Therefore, it is undesirable to mix a hardening accelerator. Furthermore, addition of inorganic filler tends to degrade the adhesion property and migration characteristics, and thus, it is undesirable to mix inorganic filler.

The adhesive resin composition of the present invention is usually dissolved in an organic solvent, and used as an adhesive solution. Examples of the organic solvent that can be used include toluol, methanol, ethanol, isopropanol, acetone, dioxolane, hexane, triethylamine, isobutyl acetate, butyl acetate, ethyl acetate, methyl ethyl ketone (MEK), methyl isobutyl ketone, cellosolves, ethylene glycol, dimethylformamide (DMF), xylene, and N-methylpyrrolidone.

The solid content concentration in the adhesive solution is preferably 5% to 60% by mass, and more preferably 10% to 50% by mass, though the concentration depends on the coating method.

The adhesive resin composition of the present invention having the above configuration has good compatibility among the component (A), the component (B), and the component (C) which are resin components. Therefore, it is possible to provide a one-part adhesive which has a high adhesion property and in which the resin components are homogenously mixed without separation or aggregation even at a high concentration of 10% by mass or more.

### [Applications]

The adhesive resin composition of the present invention having the configuration described above can provide a solution-type adhesive solution that is halogen-free, that satisfies flame retardancy of the V-0 class or the VTM-0 class in the Underwriters' Laboratories (UL) 94 standard, and that can exhibit a good adhesion property. Accordingly, the adhesive resin composition of the present invention is useful as an adhesive used for a laminate such as an adhesive sheet or a coverlay, a flexible printed wiring board, or the like by coating.

In particular, the adhesive resin composition of the present invention is a transparent solution-type adhesive that is not separated even when the adhesive resin composition is left to stand for a long time, and is good in terms of storage property. Thus, the adhesive resin composition of the present invention can stably exhibit a desired adhesive strength, and can be suitably used in production sites.

Herein, a flexible printed wiring board includes a plurality of layers produced by bonding an insulating film to a metallic foil, with a hardened material of the adhesive resin composition of the present invention therebetween. Specifically, the flexible printed board can be formed by lamination of, for example, a product (so-called three-layer substrate) prepared by applying the adhesive resin composition of the present invention onto an insulating film, drying the adhesive resin composition (to a semi-hardened state), further laminating the insulating film with a metallic foil, and then by heat-setting the resulting laminate; a product (so-called coverlay) prepared by applying the adhesive resin composition of the present invention onto an insulating film, drying the adhesive resin composition (to a semi-hardened state), and covering an exposed surface of the resulting adhesive layer with an insulating film called a separator; and a product (so-called adhesive sheet) prepared by applying the adhesive resin composition of the present invention onto a separator or a base material film, drying the adhesive resin composition (to a semi-hardened state), and covering an exposed surface with a separator; and heat-setting the resulting laminate. Note that the separator is removed when the lamination is performed.

Herein, the term “semi-hardened state” refers to a state in which an adhesive resin composition has an adhesion property. The semi-hardened state is formed by heating the adhesive resin composition of the present invention, for example, at 100° C. to 180° C. for two minutes. The term “heat-set state” refers to a state in which an epoxy resin and/or a phenoxy resin is cured by a reaction with a curing agent under heating. The heat-set state is formed by heating an adhesive layer in the semi-hardened state, for example, at 140° C. to 180° C. for 10 minutes to several hours, and further applying a pressure as required. The suitable heating time varies depending on the components and the application (for example, a substrate, a coverlay, a bonding film, or the like) of the adhesive.

It is sufficient that the three-layer substrate of the present invention includes an insulating film and a metallic foil bonded to at least one surface of the insulating film. The three-layer substrate may have a three-layer structure (so-called three-layer single-sided substrate) including an insulating film, an adhesive layer, and a metallic foil layer. Alternatively, the three-layer substrate may have a five-layer structure (so-called three-layer double-sided substrate) including a metallic foil, an adhesive layer, an electrically insulating film, an adhesive layer, and a metallic foil layer.

Examples of the insulating film include a polyimide film, a polyester film, a polyetheretherketone film, and a polyphenylene sulfide film.

Examples of the metallic foil include a copper foil and an aluminum foil. A copper foil is preferably used.

The coverlay film is a laminate used as a material that covers a surface of a flexible copper-clad laminated board, on which a wiring pattern is formed by processing a copper foil of the flexible copper-clad laminated board, so that the material protects the wiring The coverlay film includes an insulating film and an adhesive layer in the semi-hardened state, the adhesive layer being composed of the adhesive resin composition of the present invention and provided on the insulating film. Usually, a separator having a releasing property is bonded onto the adhesive layer.

The adhesive sheet includes a separator or a base material film in some cases and an adhesive layer in the semi-hardened state, the adhesive layer being composed of the adhesive resin composition of the present invention and stacked on the separator or the base material film, and is used for lamination of a substrate or bonding of a reinforcing plate. The base material film is selected in accordance with the application, and may be a heat-resistant, insulating film such as a polyimide film, a fiberglass reinforced resin sheet, or a prepreg sheet including a nonwoven fabric or the like as a base material.

### EXAMPLES

Best modes for carrying out the present invention will now be described by way of Examples. The Examples do not limit the scope of the present invention.

### [Methods for Measuring and Evaluating Adhesive Resin Composition]

### (1) Compatibility

A prepared adhesive solution was visually observed. In the case where a transparent solution was obtained (however, opacity with a degree of obscured glass was acceptable), the adhesive solution was evaluated as “O”. In the case where white turbidness was observed, and separation was observed after the adhesive solution was left to stand for one week, the adhesive solution was evaluated as “Δ”. In the case where a separation layer was generated within two hours even after forced mixing under stirring, the adhesive solution was evaluated as “x”.

### (2) Peel Strength

A prepared adhesive solution was applied onto a surface of a polyimide film having a thickness of 25 μm so that the thickness of an adhesive layer after drying was 20 μm, and dried at 150° C. for two minutes to form the adhesive layer in the semi-hardened state. A rolled copper foil having a thickness of 18 μm was stacked on this adhesive layer in the semi-hardened state. Subsequently, heating was performed at 160° C. for 40 minutes by hot pressing at a pressure of 3 MPa to prepare a flexible printed wiring board. For the prepared flexible printed wiring board, a peel strength (N/cm) was measured by pulling from the copper foil side to peel off the copper foil from the polyimide film at 23° C. in accordance with Japan Industrial Standard (HS)C 6481.

### (3) Flame Retardancy

An evaluation test of flame retardancy was conducted in accordance with UL-94 using a laminate including the polyimide film and the semi-hardened adhesive layer prepared in (2), the laminate being prepared by being heated at 160° C. for 40 minutes without applying a pressure and without being laminated with a copper foil. A laminate that conformed to the above standard (V-0 class) was evaluated as “OK”. A laminate that did not conform to the standard was evaluated as “NG”.

### [Preparation and Evaluation of Adhesive Resin Composition Nos. 1 to 15]

Adhesive solutions each having a solid content concentration of 30% by mass were prepared by mixing 180 parts by mass of a phosphorus-containing epoxy/phenoxy resin serving as the component A, 100 parts by mass of a polyamide resin serving as the component (C), and 20 parts by mass of an epoxy-containing copolymer having characteristics shown in Table I and serving as the component (B), further adding a phosphazene serving as a flame retardant and a curing agent to the mixture, and dissolved in a solvent (methyl ethyl ketone and dimethylformamide) while stirring.

As the phosphorus-containing epoxy/phenoxy resin, a 1:1 mixture of a phosphorus-containing epoxy resin FX289 and a phosphorus-containing phenoxy resin ERF001 manufactured by Tohto Kasei CO., LTD. was used. As the phosphazene, SPB 100 manufactured by Otsuka Chemical Co., Ltd. was used, and the amount of phosphazene mixed was determined so that the phosphorus content percentage relative to the solid content of each adhesive resin composition was 3.5% by mass. As the curing agent, trimellitic acid manufactured by Mitsubishi Chemical Corporation was used, and mixed in an appropriate amount calculated from the weight per epoxy equivalent.

As for the epoxy-containing copolymer, glycidyl methacrylate was used as a monomer having an epoxy group, and styrene, methyl methacrylate (MMA), acrylonitrile (AN), ethyl acrylate (EAA), or butyl acrylate (BAA) was used as an ethylenically unsaturated monomer copolymerized.

Note that a glycidyl methacrylate homopolymer, which is not copolymerized with an ethylenically unsaturated monomer, was used in No. 2. In No. 7, a 1:1 mixture of epoxy-containing copolymers used in No. 3 and No. 8 was used. In No. 9, a mixture prepared by mixing the epoxy-containing copolymers used in Nos. 8 and 11 in a ratio of 5:3 was used. In No. 10, a mixture prepared by mixing the epoxy-containing copolymers used in Nos. 8 and 11 in a ratio of 3:5 was used.

The compatibility, the peel strength, and the flame retardancy of each of the prepared adhesive solutions Nos. 1 to 15 were measured on the basis of the above evaluation methods. Tables I and II show the measurement results together with the resin blending compositions. As a reference example, an adhesive solution was prepared using an adhesive resin composition that did not contain the component (B). The compatibility, the peel strength, and the flame retardancy of this adhesive solution were also measured in the same manner. The results are shown in Table II.

Note that, in Nos. 13 to 15, the adhesive solutions were separated into two layers, and thus the peel strength and the flame retardancy were not measured.

TABLE I

| No | | 1 | 2 | 3 | 4 | 5 | 6 | 7 | 8 |
|---|---|---|---|---|---|---|---|---|---|
| Epoxy- | Molecular weight | 9000 | 10000 | 10000 | 10000 | 11000 | 14500 | 15000 | 20000 |
| containing | Weight per | 530 | 240 | 310 | 2500 | 1000 | 420 | 310 | 310 |
| copolymer | epoxy equivalent | | | | | | | | |
| | g/eq | | | | | | | | |
| | Type of | Styrene | — | MMA | Styrene | Styrene | Styrene | MMA | Styrene |
| | copolymerizable | | | | AN | | | Styrene | |
| | monomer | | | | | | | | |
| Evaluation | Compatibility | ◯ | ◯ | ◯ | ◯ | ◯ | ◯ | ◯ | ◯ |
| | Peel strength | 11 | 5.6 | 9.5 | 17.4 | 14.9 | 12.6 | 9.5 | 14.8 |
| | Flame | OK | OK | OK | OK | OK | OK | OK | OK |
| | retardancy | | | | | | | | |

TABLE II

| | | | | | | | | | Reference |
|---|---|---|---|---|---|---|---|---|---|
| No | | 9 | 10 | 11 | 12 | 13 | 14 | 15 | example |
| Epoxy- | Molecular weight | 50000 | 70000 | 100000 | 100000 | 200000 | 400000 | 850000 | — |
| containing | Weight per | 831 | 1178 | 1700 | 3300 | 340 | 14200 | 4800 | — |
| copolymer | epoxy equivalent | | | | | | | | |
| | g/eq | | | | | | | | |
| | Type of | Styrene | Styrene | Styrene | Styrene | MMA | EAA | EAA | — |
| | copolymerizable | | | | | | AN | BAA | |
| | monomer | | | | | | | AN | |
| Evaluation | Compatibility | ◯ | ◯ | Δ | Δ | X | X | X | ◯ |
| | Peel strength | 14.8 | 14.8 | 14.6 | 12.6 | — | — | — | 2.2 |
| | Flame | OK | OK | OK | OK | — | — | — | OK |
| | retardancy | | | | | | | | |

As shown in Tables I and II, when the weight-average molecular weight was 100,000 or more, the compatibility decreased (Nos. 11 and 12). When the weight-average molecular weight was 200,000 or more, the adhesive solutions were separated into two layers (Nos. 13 to 15).

Regarding the adhesive solutions (No. 1 and Nos. 3 to 12) which contained an epoxy-containing copolymer and whose peel strength could be measured, the adhesive strengths of these adhesive solutions including the adhesive solutions Nos. 11 and 12, which had poor compatibility, were each higher than the adhesive strength of the reference example, which contained no epoxy-containing copolymer.

In addition, No. 2, which is a homopolymer of an epoxy-containing copolymer, also exhibited an adhesive strength higher than that of the reference example.

FIGURE is a graph showing a relationship between the weight per epoxy equivalent (horizontal axis) and the peel strength (vertical axis) of the adhesive solutions Nos. 1 to 12. In FIGURE, symbol “x” indicates the homopolymer of the monomer having an epoxy group, and symbol “” indicates the case where acrylonitrile was used as an ethylenically unsaturated comonomer.

In FIGURE, as shown by the broken line, except for the case of the homopolymer of the monomer having an epoxy group, the peel strength also increased with an increase in the weight per epoxy equivalent up to a weight per epoxy equivalent of about 800 g/eq. The peel strength was saturated at a weight per epoxy equivalent of about 800 g/eq, and tended to gradually decrease from 3,000 g/eq. In addition, in the case where acrylonitrile was used as an ethylenically unsaturated monomer (the case indicated by symbol “” in FIGURE), the adhesive strength was higher than that of an epoxy-containing copolymer which had substantially the same weight per epoxy equivalent and in which a different ethylenically unsaturated monomer was used (the epoxy-containing copolymer assumed to be located on the broken line in FIGURE).

### INDUSTRIAL APPLICABILITY

The adhesive resin composition of the present invention can provide a one-part type adhesive solution having good storage stability. Accordingly, the adhesive resin composition of the present invention does not cause a problem of variations in the adhesion property among products in production lines or problems in terms of pot life and storage property in that stirring, washing of devices, and the like must be performed each time the resin composition is used. Thus, the adhesive resin composition of the present invention is useful for continuous or intermittent use in production lines and the like.

### CITATION LIST

### Patent Literature

PTL 1: Japanese Unexamined Patent Application Publication No. 2002-275444
PTL 2: Japanese Unexamined Patent Application Publication No. 2008-81678
PTL 3: Japanese Unexamined Patent Application Publication No. 2008-308686
PTL 4: Japanese Unexamined Patent Application Publication No. 2004-307627

1. An adhesive resin composition comprising (A) an epoxy resin and/or a phenoxy resin; (B) an epoxy-containing copolymer obtained by copolymerizing a monomer having an epoxy group and an ethylenically unsaturated monomer that is copolymerizable with the monomer having an epoxy group; (C) a thermoplastic resin; and (D) a curing agent,
wherein a copolymer having a weight-average molecular weight of 5,000 to less than 100,000 and a weight per epoxy equivalent of 3,500 g/eq or less is used as the epoxy-containing copolymer (B), and the thermoplastic resin (C) is polyamide resin.

2. The adhesive resin composition according to claim 1, wherein an ethylenically unsaturated monomer unit in the epoxy-containing copolymer (B) is at least one selected from the group consisting of styrenes, acrylonitrile, and (meth)acrylate esters.

3. The adhesive resin composition according to claim 1, wherein the content percentage of the component (A) in the resin components contained in the adhesive resin composition is 40% to 70% by mass, and the content percentage of the component (B) is 3% to 25% by mass.

4. The adhesive resin composition according to claim 1, wherein the monomer having an epoxy group in the epoxy-containing copolymer (B) is glycidyl(meth)acrylate.

5. The adhesive resin composition according to claim 1, wherein the epoxy resin and/or phenoxy resin (A) contains a phosphorus-containing epoxy resin and/or a phosphorus-containing phenoxy resin.

6. The adhesive resin composition according to claim 1, further comprising a phosphorus flame retardant, wherein the phosphorus content percentage in the resin composition is 3.1% to 4.5% by mass.

7. A one-part type adhesive solution comprising the adhesive resin composition according to claim 1, wherein the content percentage of the adhesive resin composition is 5% to 60% by mass.

8. A laminate comprising a base material film and an adhesive layer disposed on the base material film, the adhesive layer being composed of the adhesive resin composition according to claim 1.

9. A flexible printed wiring board comprising the laminate according to claim 8.
